(19) United States
(12) Patent Application Publication
(10) Pub. No.: US 2015/0053256 A1
(43) Pub. Date: Feb. 26, 2015

(54) SOLAR CELLS AND METHODS OF MAKING THEREOF

(71) Applicant: E I DU PONT DE NEMOURS AND COMPANY, Wilmington, DE (US)

(72) Inventors: DMITRY POPLAVSKYY, San Jose, CA (US); Giuseppe Scardera, Sunnyvale, CA (US); Karim Lotfi Bendimerad, San Francisco, CA (US); Daniel Aneurin Inns, Sunnyvale, CA (US)

(73) Assignee: E I DU PONT DE NEMOURS AND COMPANY, Wilmington, DE (US)

(21) Appl. No.: 13/975,723

(22) Filed: Aug. 26, 2013

(51) Int. Cl. H01L 31/0236

(52) U.S. Cl. CPC H01L 31/02363
USPC 136/252; 438/98

(57) ABSTRACT

A method of making a solar cell may include depositing in a first pattern a first ink comprising a first dopant on a back surface of a substrate that is doped with a second dopant being of the same type as the first dopant; then, depositing a second ink comprising a set of undoped semiconductor nanoparticles over the first ink on the back surface of the substrate in a second pattern matching the first pattern; then, heating the semiconductor substrate so that the first dopant diffuses into the substrate and thereby, forms a third pattern of localized doped regions; then, exposing the substrate to a doping ambient comprising a third dopant being of the opposite type to the second dopant, thereby forming a doped semiconductor layer on the front surface and a portion of the back surface not covered by the second ink, and then, removing the deposited ink.

### FIELD OF THE INVENTION

The present application relates to semiconductor electronic devices, such as solar cells, and their methods of making.

### SUMMARY

One embodiment is a method of making a solar cell comprising:

(a) obtaining a semiconductor substrate that is doped with a second dopant, the substrate having a front surface and a back surface;
(b) depositing a first ink on the back surface of the substrate in a first pattern, the first ink comprising a first dopant, the first dopant being of the same type as the second dopant;
(c) then, depositing a second ink over the deposited first ink on the back surface of the substrate in a second pattern, the second pattern matching the first pattern and the second ink comprising a set of undoped semiconductor nanoparticles;
(d) then, heating the semiconductor substrate so that the first dopant diffuses into the substrate and thereby, forms a third pattern of localized doped regions;
(e) then, exposing the substrate to a doping ambient comprising a third dopant, thereby forming a doped semiconductor layer on the front surface and a portion of the back surface not covered by the second ink, the third dopant is of the opposite type to the second dopant;
and
(f) then, removing the deposited first and second inks.

### FIGURES

FIG. 1 shows a simplified diagram of a traditional front-contact solar cell;

FIG. 2 shows a simplified diagram of a passivated layer/reduced metal contact solar cell configuration with detrimental shunting.

FIG. 3A-G illustrate a method of making a high efficiency solar cell.

FIG. 4 is a plot presenting dependence of sheet resistance of the boron doped region on the drive-in temperature. Sheet resistance is measured with a 4 point technique across a 1.6 mm wide strip of boron doped region, diffused on a 180 um thick 2 Ohm-cm p-type wafer.

FIG. 5 presents SEM contrast images showing BSF depth as a function of drive-in temperature.

### RELATED DOCUMENTS

One of ordinary skill in the art may find the following documents useful for understanding the present invention:
1) U.S. application Ser. No. 13/687,126 filed Nov. 28, 2012 published as US 2013-0153019;
2) U.S. application Ser. No. 13/099,794 filed May 3, 2011 published as US 2012-0280183;
3) U.S. application Ser. No. 13/463,050 filed May 3, 2012 published as US 2013-0119319;
4) U.S. provisional application No. 61/734,014 filed Dec. 6, 2012;
5) U.S. application Ser. No. 13/795,191 filed Mar. 12, 2013.

### DETAILED DESCRIPTION

Unless otherwise specified, “a” or “an” means one or more.

A solar cell converts solar energy directly to DC electric energy. Generally configured as a photodiode, it permits light to penetrate into the vicinity of metal electrodes (metal contacts) such that a generated charge carrier (electrons and/or holes (a lack of electrons)) may be extracted as current. And like most other diodes, photodiodes are formed by combining p-type and n-type semiconductors to form a junction.

Electrons on the p-type side of the junction within the electric field (or built-in potential) may then be attracted to the n-type region (usually doped with phosphorous) and repelled from the p-type region (usually doped with boron), whereas holes within the electric field on the n-type side of the junction may then be attracted to the p-type region and repelled from the n-type region. Generally, the n-type region and/or the p-type region can each respectively be comprised of varying levels of relative dopant concentration, often shown as n−, n+, n++, p−, p+, p++, etc. The built-in potential and thus magnitude of electric field generally depend on the level of doping between two adjacent layers.

Most solar cells are generally formed on a silicon substrate doped with a first dopant (commonly boron) forming an absorber region, upon which a second counter dopant (commonly phosphorous) is diffused forming the emitter region, in order to complete the p-n junction. After the addition of passivation, back surface field (BSF), and antireflection coatings, metal electrodes (fingers and busbar on the emitter and pads on the back of the absorber) may be added in order to extract generated charge. The BSF, in particular, must be optimized for both carrier collection and for contact with the metal electrodes.

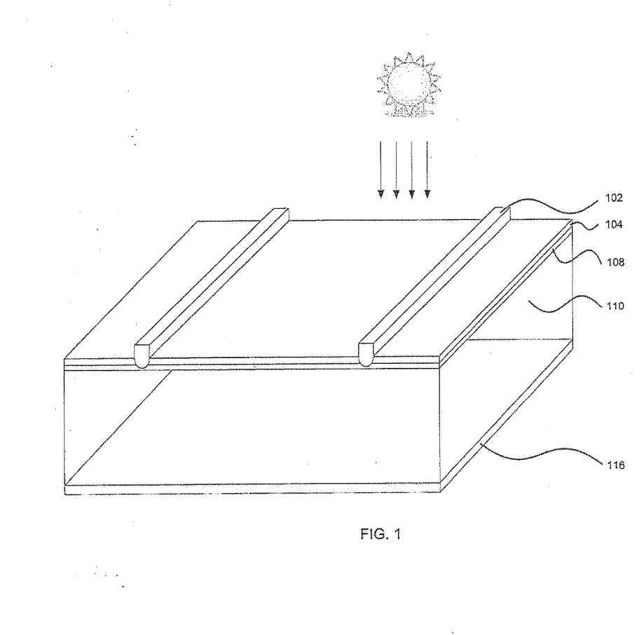

Referring to FIG. 1, a simplified diagram of a traditional front-contact solar cell is shown. In a common configuration, a phosphorous-doped (n-type) emitter region 108 is first formed on a boron-doped silicon substrate 110 (p-type), although a configuration with a boron-doped emitter region on a phosphorus-doped silicon substrate may also be used.

Prior to the deposition of silicon nitride (SiNₓ) layer 104 on the front of the silicon substrate, residual surface glass (PSG) formed on the silicon substrate surface during the POCl₃ deposition process may be removed by exposing the doped silicon substrate to an etchant, such as hydrofluoric acid (HF). The set of metal electrodes, comprising front-metal electrode 102 and back surface field (BSF)/rear metal contact 116, are then sequentially formed on and subsequently fired into the substrate.

The front metal electrode 102 is commonly formed by depositing an Ag (silver) paste, comprising Ag powder (about 70 to about 80 wt % (weight percent)), glass frit (about 1 to about 10 wt %), and organic components (about 15 to about 30 wt %). After deposition the paste is dried at a low temperature to remove organic solvents and fired at high temperatures to form the conductive metal layer and to enable the silicon-metal electrode.

BSF/rear metal contact 116 is generally formed from aluminum (in the case of a p-type silicon substrate) and is configured to create a potential barrier that repels and thus minimizes the impact of minority carrier rear surface recombination. In addition, Ag pads [not shown] are generally applied onto BSF/rear metal contract 116 in order to facilitate soldering for interconnection into modules.

However, the use of an aluminum BSF may also be problematic. An aluminum BSF tends to cause solar cell warping, which leads to difficulties in subsequent production processes and decreases the yield due to increased breakage. In addition, not only does an aluminum BSF tend to form a suboptimal reflection surface, reducing the amount of long wavelength light that would otherwise be reflected back into the wafer substrate, but it is also not generally the best form of rear passivation available.

One solution is to replace the aluminum BSF with a more reflective and better passivating layer and to further reduce the rear metal contact area. Consequently, charge carrier recombination at the back surface will tend to be reduced and the absorption of long wavelength light will tend to be increased.

Solar cells configured with this architecture are commonly referred to as PERC (Passivated Emitter and Rear Cell) an architecture that was first introduced in 1989 by the University of New South Wales [A. W. Blakers, et al., Applied Physics Letters, 55 (1989) 1363-1365]. The devices fabricated in that study used heavily doped substrates as well as numerous expensive processing steps that are not compatible with high throughput manufacturing. Other versions of this cell architecture were later introduced as options to further increase the efficiency. Most notable among them is the PERL (passivated emitter rear locally diffused) [A. Wang, et al. J. Appl. Phys. Lett. 57, 602, (1990)] and PERF (passivated emitter rear floating junction) cells [P. P. Alternatt, et al. J. Appl. Phys. 80 (6), September 1996, pp. 3574-3586]. Similar to the original PERC cell, these architectures are expensive to manufacture. Since their introduction there have been numerous attempts to develop an industrially viable approach to make these cells.

One important feature of these cells is the passivation layer on the rear surface. One approach is to use the residual rear phosphorous diffusion, created during the front-side phosphorous diffusion process (or in a separate diffusion step), provided it is disconnected from the front junction. This type of passivation is referred to as a rear diffused floating junction and has been shown to provide excellent quality rear passivation [C. B. Honsberg, Solar Energy Materials and Solar Cells 34, Issues 1-4, 1 Sep. 1994, Pages 117-123]. An alternative type of floating junction can be formed by putting a dielectric layer that contains fixed positive charge (e.g. silicon nitride) onto lightly p-type silicon (i.e. the wafer bulk). In this case the fixed charge creates an inversion layer in the silicon which serves to passivate the silicon surface in a similar way to an n-type diffusion. This case may be referred to as an induced floating junction.

Floating junctions provide excellent rear surface passivation, but are also generally susceptible to the formation of a shunt between the rear metal electrode and the counter-doped areas (floating junction) at the rear of the silicon substrate. This shunt path greatly reduces the passivation provided by the floating junction, resulting in reduced cell efficiency [S. Dauwe, et al. Prog. Photovolt: Res. Appl. 2002; 10:271-278].

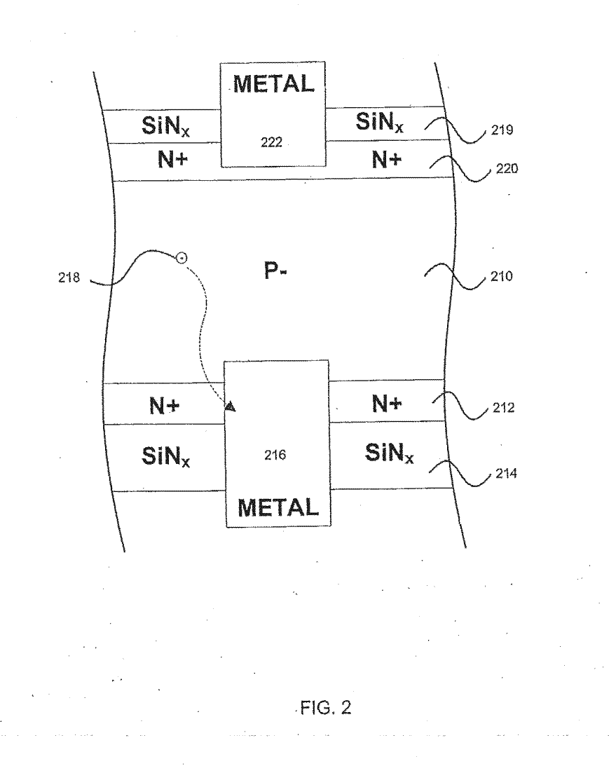

Referring now to FIG. 2, a simplified diagram is shown of detrimental shunting in a rear metal reduced area solar cell configuration on a p-type (boron doped) substrate 210 with an n-type emitter layer. Here, a set of front metal electrodes 222 connects to n+ emitter region 220 through front surface SiNx layer 219 in order to make an ohmic contact. n+ emitter region 220 is generally formed with a POCl₃ diffusion process. SiNx layer 219 is generally configured to passivate the front surface as well as to minimize light reflection from the top surface of the solar cell. Likewise, the set of rear metal electrodes 216 connects with the p-bulk region 210 through back surface SiNx layer 214 in order to make an ohmic contact to the back-side of the cell. However, a residual n+ region 212, created during the POCl₃ process to form n+ emitter region 220, creates a shunting pathway for charge carrier 218, which can substantially reduce any generated current as well as the overall solar cell efficiency.

US 2013-0153019 provides one solution of the discussed above problem. The present application may provide an alternative solution to the above discussed problem.

The present invention provides a process for making a localized back-surface-field (L-BSF) solar cell structure which may yield a higher efficiency, compared to a standard solar cell process.

In some embodiments, the method of making a high efficiency solar cell may as follows.

First, a doped semiconductor substrate, such as a doped semiconductor wafer, having a front surface and a back surface, may be obtained. The back surface is usually parallel or substantially parallel to the front surface. The substrate may comprise a Group IV semiconductor, such as silicon or germanium. In case of the silicon containing substrate, it may include monocrystalline silicon, polycrystalline silicon or silicon admixed with one or more other elements such as germanium or carbon. The substrate may be n-doped or p-doped. In many embodiments, a p-doped substrate, which may be doped, for example, with boron atoms, may be preferred.

In some embodiments, the substrate may exposed to a base solution, such as a KOH solution or NaOH solution. Such exposure may provide texturing, such as random pyramid texturing, of one or both of the substrate's surfaces. Such texturing may enhance light trapping by the produced solar cell and thus increase photogenerated current.

In some embodiments, the substrate may be cleaned to remove contaminants from one or both of its surfaces. Such cleaning may be performed using an acidic media, such as a mixture of HF:HCl. In many embodiments, the cleaning may follow the above disclosed texturing.

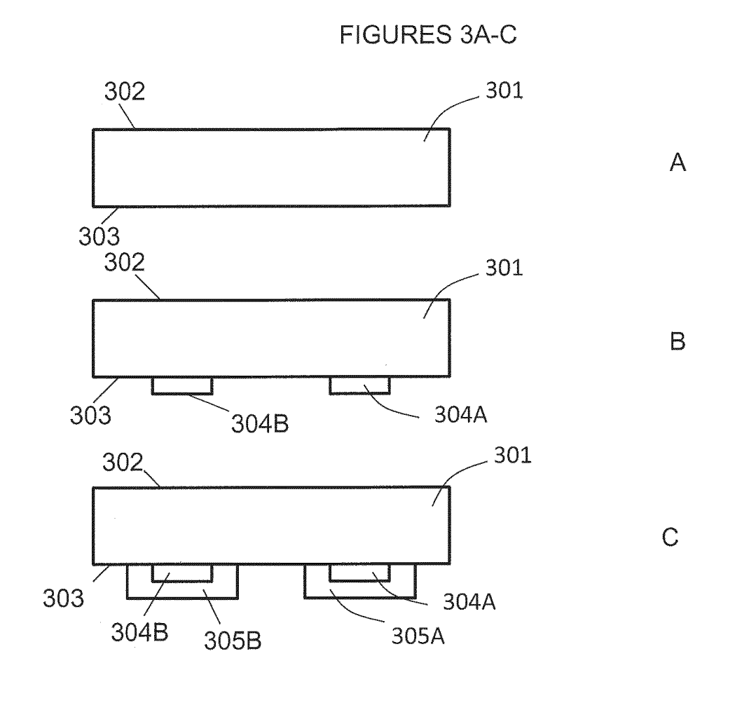

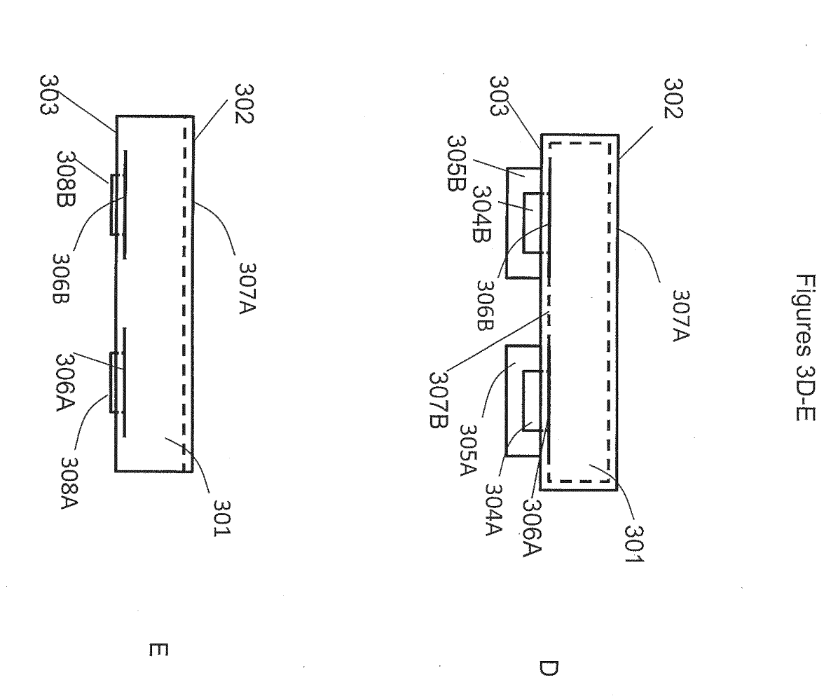

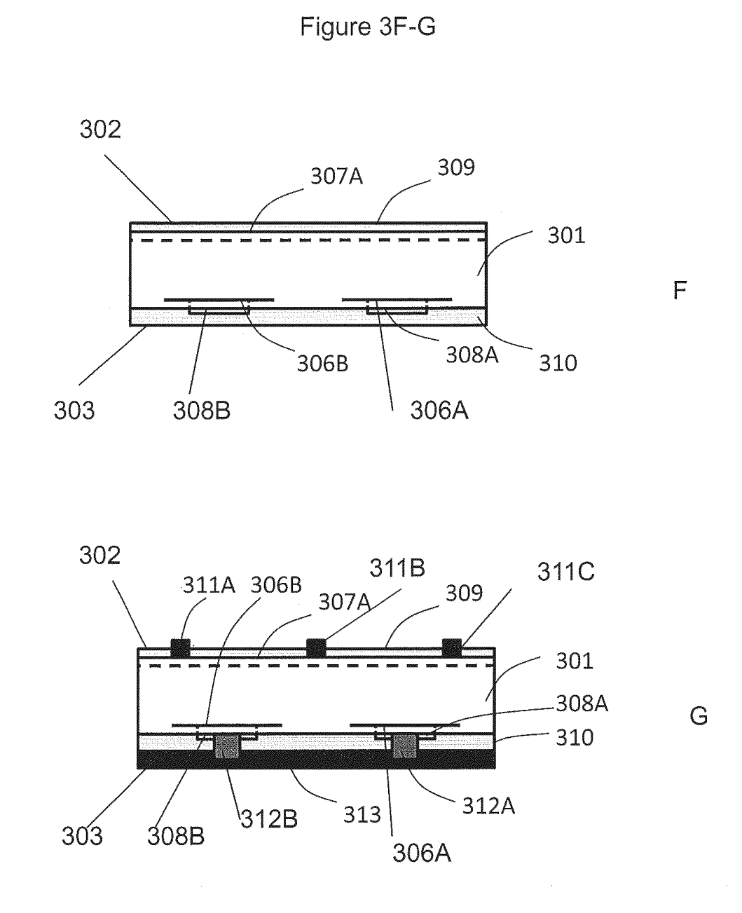

FIG. 3A illustrates a substrate 301, which may be a mononocrystalline p-type silicon wafer. The substrate 301 has a front surface 302 and a back surface 303. The substrate's surfaces 302 and 303 may be textured in a KOH solution to form a random pyramid texture for enhanced light trapping. After texturing, the substrate 101 may be cleaned in a mixture to remove residual contaminants from its surface(s) 302 and/or 303.

Second, a first (doping) composition may be deposited of the back surface of the substrate in a first pattern. The first (doping) composition contains a dopant of the same type as a dopant of the substrate. In other words, if the substrate is p-doped, the dopant in the first (doping) composition is also of p-type; while when the substrate is n-doped, the dopant in the first (doping) composition is of n-type. For the p-doped substrate, the p-type dopant in the first composition may be, for example, a boron-containing material. The boron-containing material may be, for example, one or more of the following: boron (B), boron nitride (BN), boron oxide (B₂O₃), boric acid (B(OH)₃), boron carbide (B₄C), boron silicide (B₂Si, B₃Si, B₄Si, B₆Si), boron-doped group IV nanoparticles (such as nc-Si:B), aluminum boride (AlB₂), barium boride (BaB₆), calcium boride (CaB₆), cerium boride (CeB₆), chromium boride (CrB), cobalt boride (Co₂B—Co₃B), dysprosium boride (DyB₄, DyB₆), erbium boride (ErB₄), europium boride (EuB₆), gadolinium boride (GdB₆), hafnium boride (HfB₂), holmium boride (HoB₄), iron boride (Fe₂B), lanthanum boride (LaB₆), lutetium boride (LuB₄), magnesium boride (MgB₂), manganese boride (MnB, MnB₂), molybdenum boride (MoB), neodymium boride (NdB₆), nickel boride (NiB), niobium boride (NbB₂), praseodymium boride (PrB₆), rhenium boride (Re₇B₃), samarium boride (SmB₆, scandium boride (ScB₂), strontium boride (SrB₆), tantalum boride (TaB₂), terbium boride (TbB₆), thulium boride (TmB₄), titanium boride (TiB₂), tungsten boride (WB, W₂B, W₂B₅), vanadium boride (VB₂), ytterbium boride (YbB₆), and zirconium boride (ZrB₂, ZrB₁₂). The purity of the boron-containing material is generally not limited. In some embodiments, the purity of the boron-containing material may more than 95 mol % or more than 97 mol % or more than 99 mol %. In some embodiments, two or more boron-containing materials may be used in a mixture in the first (doping) composition.

In some embodiments, the dopant, such as a p-type dopant, may constitute between 0.5 and 20 wt % or between 1 and 10 wt % based on the total weight of the first (doping) composition.

In some embodiments, the first (doping) composition may further include one or more ceramic particles. The ceramic particle(s) may contain one or more of the following: SiN, SiO₂, SiC, TiO₂, Al₂O₃, MgO, CaO, Li₂O, BeO, SrO, Sc₂O₃, Y₂O₃, La₂O₃, CeO₂, Ce₂O₃, Pr₂O₃, Nd₂O₃, Sm₂O₃, EuO, Gd₂O₃, Ta₂O₅, Tb₂O₃, Dy₂O₃, Ho₂O₃, Er₂O₃, Tm₂O₃, Yb₂O₃, Lu₂O₃, ThO₂, UO₂, ZrO₂ and HfO₂. In some embodiments, the ceramic particle may be selected from the group consisting of titanium oxide (TiO₂), aluminum oxide (Al₂O₃), magnesium oxide (MgO), tantalum oxide (Ta₂O₅), and zirconium oxide (ZrO2), and combinations thereof. The purity of the ceramic particle is not limited. For example, the purity of the ceramic particle may be more than 95 mol % or more than 97 mol % or more than 99 mol %. In some embodiments, two or more types of the ceramic particles may be used in mixture.

The use of the ceramic material in the first (doping) composition may reduce undesired processes during a high temperature diffusion process. For example, in the case of a boron containing material, during the high temperature diffusion process, boron may be allowed to diffuse into the substrate, while the diffusion of ambient phosphorous may be blocked or substantially reduced by the ceramic material. A particular material for the ceramic particle(s) may be selected depending on the properties of the underlying semiconductor substrate. For example, some oxide materials, which may be used as ceramic particles, may get reduced in contact with silicon at an elevated temperature thereby introducing impurities into the silicon substrate.

In some embodiments, a surface of the ceramic particle may be treated with a ligand or capping agent in order to disperse it in a set of solvents and optimize shear thinning behavior. In general, a capping agent or ligand is a set of atoms or groups of atoms bound to a “central atom” in a polyatomic molecular entity. The capping agent is selected for some property or function not possessed by the underlying surface to which it may be attached.

Selection and modification of ceramic particle(s), is disclosed, for example, in K. J. Hubbard and D. G. Schlom, Thermodynamic stability of binary metal oxides in contact with Silicon, J. Mater. Research, v 11(11), 1996) and US 2012-0280183.

In some embodiments, the ceramic particles may constitute between 3 and 50 wt % or between 5 and 30 wt % of the total weight of the first (doping) composition. In some embodiments, the first (doping) composition may further include a polymer binder. Such binder may be used to modify a viscoelastic behavior of the first (doping) composition. For example, in some embodiments, a polymer binder may be included in the first (doping) composition in order to optimize its viscoelastic behavior for screen printing. The polymer binder may be, for example, one or more of the following: polyacrylates, polyacetals and their derivatives, polyvinyls, a cellulose (including its ethers and esters), and copolymers thereof. Two or more types of the polymer binder may be used in mixture.

In some embodiments, the polymer binder may constitute between 0.5 and 3 wt % or between 0.75 and 2 wt % based on the total weight of the first (doping) composition.

One or more components of the first (doping) composition may be dispersed in a solvent, which may be, for example, one or more of the following: alcohols, aldehydes, ketones, carboxylic acids, esters, amines, organosiloxanes, halogenated hydrocarbons, and other hydrocarbon solvents. In some embodiments, two or more solvents may be used in order to modify one or more physical characteristic of the first (doping) composition, such as viscosity, density, polarity, etc.

The first (doping) composition may be deposited using a number of techniques. In some embodiments, a printing technique, such as screen printing may be used for such deposition. In certain embodiments, the first (doping) composition may be in a form of a paste or an ink. In certain embodiments, it may be preferred to use the first (doping) composition in a form of a non-Newtonian or shear-thinning fluid. Using the first (doping) composition in such a form may provide a better efficiency and/or performance for screen printing. Non-Newtonian/shear thinning fluids are generally known, see e.g. US 2013-0153019.

Compositions that may be used the first doping composition are disclosed, for example, in US 2012-0280183.

Preferably, the first composition is deposited in a form of a pattern. In some embodiments, such a pattern may be an array comprising a plurality of individual features comprising the first (doping) composition. Each individual feature may have a regular or irregular shape. Non-limiting examples of regular shapes include squares, circles, rectangles and ellipses. A particular size of the individual feature may depend on an application. In some embodiments, a maximum characteristic size of the feature may range, from 50 μm to 1000 μm or from 100 μm to 800 μm or from 200 μm to 500 μm or any subrange within these ranges. In some embodiments, the individual features may be separated from each other by a distance ranging from 0.1 mm to 5 mm or from 0.2 mm to 3 mm or from 0.5 mm to 2 mm or any subrange within these ranges.

Following the deposition of the first (doping) composition, the substrate may be heat treated. Parameters of such heat treatment, such as temperature and time, may be selected to be such so that the heat treatment results in evaporation of the solvent from the deposited composition, while not burning a polymer binder, which may be present in the composition. In some embodiments, the heat treatment may be performed at a temperature ranging from 125° C. to 275° C. or from 150° C. to 250° C. or from 175° C. to 225° C. for a period of time which may range from 0.25 min to 3 min or from 0.5 min to 2 min. Methods for evaporating the solvent from the deposited first (doping) composition, other than heat treatment, may be also used. FIG. 3B illustrates deposition of the first (doping) composition on the back surface 302 of the substrate 301 in a form of two individual features 304A and 304B, which may form a pattern, such as an array.

Following the deposition of the first (doping) composition, a second (capping) composition may be deposited over the deposited first (doping) composition in a pattern that matches the pattern of the first (doping) composition. Preferably, each individual feature of the second (capping) composition covers a respective feature of the first (doping) composition so that it caps it. FIG. 3C illustrates deposition of the second (capping) composition in a form of individual features 305A and 305B, which cap features of the deposited first (doping) composition 304A and 304B, respectively.

The second (capping) composition may comprise one or more undoped semiconductor nanoparticles. In some embodiments, such nanoparticles may Group IV undoped nanoparticles, such as undoped silicon or germanium nanoparticles. In addition, the second (capping) composition may comprise one or more ceramic particles. The ceramic particles used in the second (capping) composition may be selected from the types of ceramic particles listed above for the first (doping) composition although particular ceramic particles used in the second (capping) composition may or may not be of the same type as ceramic particles used in the first (doping) composition. In some embodiments, the second (capping) composition may further include a polymer binder. Such polymer binder may be selected from the types of polymer binders listed above for the first (doping) composition although a particular polymer binder used in the second (capping) composition may or may not be of the same type as a polymer binder used in the first (doping) composition.

One or more components of the second (capping) composition may be dispersed in a solvent, which may be, for example, one or more of the following: alcohols, aldehydes, ketones, carboxylic acids, esters, amines, organosiloxanes, halogenated hydrocarbons, and other hydrocarbon solvents. In some embodiments, two or more solvents may be used in order to modify one or more physical characteristic of the composition, such as viscosity, density, polarity, etc.

The second (capping) composition may be deposited using a number of techniques. In some embodiments, a printing technique, such as screen printing may be used for such deposition. In certain embodiments, the second (capping) composition may be in a form of a paste or an ink. In certain embodiments, it may be preferred to use the composition in a form of a non-Newtonian or shear-thinning fluid. Using the second (capping) composition in such a form may provide a better efficiency and/or performance for screen printing. Compositions that may be used the second capping composition are disclosed, for example, in U.S. provisional application No. 61/734,014.

Individual features of the deposited second (capping) composition may be slightly larger than the individual features of the deposited first (doping) composition to allow for an alignment tolerance. In certain embodiments, a characteristic size of an individual feature of the deposited second (capping) composition may be from 1.05 to 2 times or from 1.1 to 1.9 or from 1.2 to 1.8 or any value or subrange within these ranges of the characteristic size of an individual feature of the deposited first (doping) composition.

Following the deposition of the second (capping) composition, the substrate may be heat treated. Parameters of such heat treatment, such as a temperature and time, may be selected to be such so that the heat treatment results in evaporation of the solvent from the deposited composition, while not burning a polymer binder, which may be present in the composition. In some embodiments, the heat treatment may be performed at a temperature ranging from 125° C. to 275° C. or from 150° C. to 250° C. or from 175° C. to 225° C. for a period of time which may range from 0.25 min to 3 min or from 0.5 min to 2 min. Methods for evaporating the solvent from the deposited composition, other than heat treatment, may be also used.

Following the deposition of the second (capping) composition, the substrate may be heat treated so than the dopant of the first (doping) composition diffuses into the substrate, thereby forming a pattern of localized doped regions in proximity of the back surface of the substrate.

FIG. 3D illustrates a formation of localized doped regions 306A and 306B from the individual features 304A and 304B, respectively, of the deposited first (doping) composition by diffusing the dopant of the first (doping) composition into the substrate 301. When the substrate 301 is a p-doped substrate, the dopant forming localized doped regions 306A and 306B may be a p-type dopant, such as boron, present in the individual features 304A and 304B of the first (doping) composition. Particular conditions, such as temperature and time, for the heat treatment resulting in formation of the localized doped regions through the diffusion of the dopant of the first (doping) composition into the substrate may depend on a particular type of the dopant in the first (doping) composition. For example, when such a dopant comprises a boron containing material, the temperature of the heat treatment may be from 850° C. to 1025° C. or from 900° C. to 975° C. or any temperature or a subrange within these ranges. The time of the heat treatment in the case of the boron-containing material may be from 0.25 hours to 3 hours or from 0.5 hours to 2 hours or any time or a subrange within these ranges.

The heat treatment may be performed in a gaseous ambient comprising at least one inert or oxidizing gas. Examples of inert gases include nitrogen and argon. One example of an oxidizing gas may be oxygen. In some embodiments, the gaseous ambient may be N₂:O₂ ambient.

Prior to the heat treatment resulting in formation of the localized doped regions, the substrate may be cleaned. The purpose of the cleaning may be to remove contaminants and/or a native oxide that may be present on the surface of the substrate. The cleaning may be performed in a wet cleaning solution, which may contain one or more of the following: HCl, HF, H₂O₂, ammonium hydroxide and de-ionized water (DIW). Examples of cleaning solutions include, but not limited to, an HF/HCl solution, such as a solution of 7% HF with 5% HCl in DIW, a SC1 solution (a mixture of ammonium hydroxide, H₂O₂ and DIW) or a SC2 solution (a mixture of HCl, H₂O₂ and DIW).

Following the heat treatment leading to diffusion of the dopant of the first (doping) composition into the substrate, the substrate may be exposed to a gaseous doping ambient. A dopant of this doping ambient has a type opposite to the type of both the initial dopant of the substrate and the dopant of the first (doping) composition. In other words, when the initial substrate is p-doped and the dopant of the first (doping) composition is a p-type dopant, such as boron, the dopant of the gaseous doping ambient comprises an n-type dopant and vice versa. The exposure of the substrate to the gaseous doping ambient may result in a formation of a doped glass layer in areas in a proximity of the substrate's surface, which are not protected by the deposited second (capping) composition. Such areas may include the full front surface of the substrate as well portions of the back surface, which are not covered by the deposited second (capping) composition. In some embodiments, the exposure to the gaseous doping ambient may also lead to formation of a doped glass layer on the areas of the substrate's surface, which are not protected by the deposited second (capping) composition, through a reaction of the dopant in the gaseous doping ambient with an oxidizing gas, such as oxygen, which may be also present in the gaseous doping ambient. A SiO₂.P₂O₅ layer, also known as a PSG layer, may be an example of the doped glass layer. The doped glass layer may lead to the formation of a doped semiconductor layer in the substrate underneath, as the result of a termally activated diffusion of the dopants from the glass layer during the heat treatment step.

In FIG. 3D, areas 307A and 307B represent a doped semiconductor layer formed in a proximity of the areas of the surface of the substrate 301, which are not covered by the individual features 305A and 305B of the deposited second (capping) composition. When the initial substrate 301 is p-doped, the doped semiconductor layer (307A and 307B) is n-doped. The area 307A represents the doped semiconductor layer on the front surface 302 of the substrate 301, while the areas 307B represent the doped semiconductor layer in the exposed areas of the back surface 303 of the substrate 301.

In many embodiments, the gaseous doping ambient may comprise a phosphorous containing gas. Examples of phosphorous containing gases include PH₃, PHCl₂, PH₂Cl, PCl₃, and POCl₃. In some embodiments, the gaseous doping ambient may be formed by flowing a phosphorous containing gas, such as POCl₃, into a gaseous ambient comprising at least one oxidizing gas, such as O₂. For example, in some embodiments, POCl₃ may be flowed in a N₂:O₂ gaseous ambient. The reaction between POCl₃ and oxygen may result in formation of a) P₂O₅ on the exposed substrate's surface and b) Cl₂ gas, which may interact and remove metal impurities from the exposed substrate's surface. The formed P₂O₅ may in turn react with the substrate. For example, for a silicon substrate, such reaction may result in formation of SiO₂ and free P atoms. The simultaneous oxidation of the silicon substrate may result in the formation of a SiO₂.P₂O₅ layer (PSG or phosphosilicate glass).

Following the exposure of the substrate to the gaseous semiconductor layer, the remaining second (capping) composition and/or the remaining first (doping) composition may be removed or thinned from the back surface of the substrate. In some embodiments, the doped semiconductor oxide layer may be also removed at least from a portion of the front and back surface of the substrate. As discussed below, in some embodiments, the doped semiconductor layer may be removed selectively only from the exposed areas of the back surface of the substrate, i.e. the areas of the back surface of the substrates not covered by the first (doping) composition, while leaving the doped semiconductor layer on the front surface of the substrate intact.

In some embodiments, the removal of the remaining second (capping) composition and/or the remaining first (doping) composition may involve ultra-sonication of the substrate or spraying a substrate with a solvent, such as de-ionized water.

In some embodiments, the removal of the remaining second (capping) composition and/or the remaining first (doping) composition and/or the doped semiconductor oxide layer may involve etching the substrate. Such etching may be performed by exposing the substrate to an etchant, such as hydrofluoric acid (HF). Such exposure may remove the doped semiconductor oxide layer, such as a PSG layer. Such exposure may also thin and/or remove the remaining second (capping) composition and/or the remaining first (doping) composition.

In some embodiments, the doped semiconductor layer may be selectively removed, which may be mean that the removal of the doped semiconductor layer on the exposed, i.e. not covered or effected by the first (doping) composition, areas of the back surface of the substrate, while leaving the doped semiconductor layer on the front surface of the substrate. In some embodiments, a thickness of the removed doped semiconductor layer may be between 0.05 and 5 μm.

To remove the doped semiconductor layer, an etchant, such as an etchant comprising HF, may be applied first to the back side of the substrate to etch the doped oxide layer, such as the PSG layer. This removal may be selective to the back side. For example, a RENA InOxSide® tool may allow removing the doped oxide layer, such as the PSG layer, only from the back side of the substrate by floating the substrate in the etchant so that the etching happens only on the back-side of the substrate. If removal of the doped oxide layer, such as the PSG layer, is desired on both the front and back sides of the substrate, a full immersion tool, such as e.g. the RENA InOx®, may be used. After removal of the doped oxide layer, such as the PSG layer, an etch solution may be used to selectively etch the substrate's material, which may be silicon in case of the silicon substrate, on the back side from the areas not covered by the first (doping) composition. For a silicon substrate, such etch solution may comprise one or more of KOH, NaOH, tetramethylammonium hydroxide (TMAH) and isopropyl alcohol (IPA). For example, in some embodiments, the etch solution may be 25% KOH, 2% IPA solution applied at between 45 C and 65 C for 1 to 30 minutes. In some embodiments, the etch solution for etching a silicon substrate may comprise one or more acid, such as HNO₃ and HF. In some embodiments, a mixture of HNO₃ and HF may be used. In some embodiments, the etch may be designed to achieve selectivity to the heavily p-type doped areas as given by the etch selectivity chart published in “Highly Selective KOH-Based Etchant for Boron-Doped Silicon Structures” by E. Bassous and A. C. Lamberti, IBM Research Division, Thomas J. Watson Research Center, Yorktown Heights, N.Y. 10598, USA. Microelectronic Engineering 9 (1989) 167-170. Additionally, in some embodiments, the boron containing first (doping) composition may be designed to further mask the substrate's surface during the etching process by creating a barrier between the substrate's material and the etch solution. By selectively etching the back side the resulting solar cell may have enhanced reflection at the rear and reduced recombination due to the reduction in surface area. Following the etching, the substrate may be cleaned. Such cleaning may be performed using a heated mixture of H₂O₂, HCl and water, followed by HF:HCl mixture. The cleaning may prepare the substrate for depositing a passivating layer. FIG. 3E illustrates the substrate 301 after the removal of the second (capping) composition (removal of individual features 305A and 305B of the second (capping) composition) and the selective removal of the doped semiconductor layer. As FIG. 3E shows, the selective removal results in removal of the doped semiconductor layer 307B from the back surface 303 of the substrate 301, at the same time the doped semiconductor layer 307A on the front surface 302 of the substrate 301 remain intact. The removal of the second (capping) composition may also result in removal or thinning of the underlying first doping composition. FIG. 3E illustrates the “thinning” scenario by showing regions 308A and 308B formed by thinning of the individual features 305A and 305B of the deposited first (doping) composition. In some embodiments, a passivating film may be deposited on one or both of the front and back surface of the substrate. Such passivating film may comprise at least one of silicon nitride, aluminum oxide and silicon oxide. In some embodiments, the passivating film may be a stack structure comprising multiple, i.e. two or more layers. Such stack structure may include at least one layer comprising silicon nitride and at least one layer comprising one of silicon oxide and aluminum oxide. The passivating film may be prepared using a number of techniques. In some embodiments, the passivating film may be deposited using a chemical vapor deposition technique, such as plasma enhanced chemical vapor deposition (PECVD). Passivating films deposited on the back and front surfaces of the substrate may be the same or different. In some embodiments, a passivating film on the back surface of the substrate may be thicker than the one on the front surface of the substrate, while in some other embodiments, a passivating film on the back surface of the substrate may be thinner than the one on the front surface of the substrate. A thickness of the passivating film may vary. In some embodiments, such thickness may be from 30 nm to 300 nm or from 50 nm to 250 nm or any value or subrange within these ranges. FIG. 3F illustrates deposition of i) a passivating film 309 on the front surface 302 of the substrate 301 over the doped semiconductor layer 307A and ii) a passivating film 310 on the back surface 303 of the substrate 301. The film 310 is shown to be thicker than the film 309 only for illustrative purposes.

Front and back electrical contacts may be deposited on the front and back surface of the substrate to form an electrical device, such as a solar cell. The front electrical contact may be deposited so that it forms an ohmic contact with the doped semiconductor layer on the front surface of the substrate, while the back electrical contact may be deposited so that it forms an ohmic contact with the localized doped regions on the back surface of the substrate.

In some embodiments, one or more front electrical contacts may be deposited by depositing on the front surface of the substrate a conducting composition, such as a dispersion or a paste, comprising one or more electrically conducting materials, such as metals. In some embodiments, the conducting composition may be a dispersion or a paste comprising Ag. Such a dispersion or a paste may contain Ag powder, which may constitute 60 to 90 wt % or 70 to 80 wt % of the paste, dispersed in one or more organic components. The dispersion or the paste may further contain one or more a glass component, such as a glass frit, which may comprise, for example, lead borosilicate glass PbO—B₂O₃—SiO₂. In some embodiments, the glass component may constitute from 0.5 to 20% or 1 to 10% of the dispersion or the paste. The dispersion or paste may be designed to be such so that upon firing or heat treatment, it may penetrate through the passivating layer on the front surface of the substrate to form an ohmic contact to the doped semiconductor layer underneath. Pastes that may be used for forming front electrical contacts are disclosed, for example, in the U.S. application Ser. No. 13/795,191.

In some embodiments, depositing one or more back electrical contacts may be performed in several, i.e. two or more steps. In some embodiments, depositing one or more back electrical contacts may involve depositing on the back surface of the substrate a patterned conductive layer, which may be a patterned metal layer. The patterned conductive layer preferably, is aligned with the initial pattern of the deposited first (doping) composition (and thus with the pattern of the doped localized regions) on the back surface of the substrate. Depositing the patterned conductive layer, such as a patterned metal layer, may involve depositing a composition comprising one or more electrically conductive materials, such as a metal. In many embodiments, such a composition may be in a form of a paste or dispersion comprising a metal powder dispersed in an organic medium. Pastes and dispersions, which may be used for depositing the patterned conductive layer, are disclosed, for example, in U.S. application Ser. No. 13/795,191. In certain embodiments, the composition used to deposit the patterned conductive layer may be a paste or dispersion comprising at least one Ag and Al. A number of techniques may be used for depositing the patterned conductive layer. In certain embodiments, the patterned conductive layer, preferably in a form of a paste or dispersion, may be deposited by a printing technique, such as screen printing.

Following the deposition of the patterned conductive layer on the back surface of the substrate, a second unpatterned conductive layer may be deposited over the patterned conductive layer deposited on the back surface of the substrate. The unpatterned conductive layer may electrically connect two or more individual features of the patterned conductive layer. Preferably, the unpatterned conductive layer electrically connects all of the individual features of the patterned conducting layer. The unpatterned conductive layer may comprise one or more metals, such as silver, aluminum, tin, nickel and copper. Depositing the unpatterned conductive layer, such as an unpatterned metal layer, may involve depositing a composition comprising one or more electrically conductive materials, such as a metal. In many embodiments, such a composition may be in a form of a paste or dispersion comprising a metal powder dispersed in an organic medium. Pastes and dispersions, which may be used for depositing the unpatterned conductive layer, are disclosed, for example, in U.S. application Ser. No. 13/795,191. In certain embodiments, the composition used to deposit the unpatterned conductive layer may be a paste or dispersion comprising a powder of at least one silver, aluminum, tin, nickel and copper dispersed in an organic medium. A number of techniques may be used for depositing the unpatterned conductive layer. In certain embodiments, the unpatterned conductive layer, preferably in a form of a paste or dispersion, may be deposited by a printing technique, such as screen printing. The unpatterned conductive layer may have a thickness ranging from 5 μm to 50 μm or from 10 μm to 40 μm or any value or subrange within these ranges.

Upon the deposition of the front and back electrical contacts, the substrate may be exposed to an elevated temperature, which may range from 700° C. to 900° C. or from 750° C. to 850° C. Such exposure, also known as firing, may allow, for example, for the conductive material deposited on the front and back surfaces of the substrate to penetrate a respective passivating layer in order to establish an ohmic contact with the substrate. For example, the firing may allow the metal of the conducting composition, which is deposited on the front surface of the substrate, to penetrate through the passivating layer deposited on the front surface of the substrate in order to establish an ohmic contact with the underlying doped semiconductor layer in proximity of the front surface of the substrate. The firing may also allow the metal of the patterned conductive layer deposited on the back surface of the substrate to penetrate through the passivating layer on the back surface of the substrate so that individual features of the patterned conductive layer establish an ohmic contact with respective localized doped regions in proximity of the back surface of the substrate. In addition, the firing may also allow densification of the unpatterned metal layer and establishing an ohmic contact between the patterned and unpatterned layers on the back surface of the substrate. Optionally, in an alternative embodiment, firing the contacts may be performed prior to the deposition of the unpatterned metal layer, followed by the deposition of the unpatterned metal layer, which may be then annealed at a lower temperature, which may be, for example, between 100 and 400° C.

The firing may be performed using a number of devices. In some embodiments, the firing may be performed by placing the substrate into a furnace or an oven. In some embodiment, the firing device, such as a furnace or an oven, may be equipped with a conveyor in order to process multiple substrates with high throughput.

FIG. 3G illustrates front and back electrical contacts on the substrate 301. The front electrical contacts are represented by elements 311A, B, C. In some embodiments, front electrical contacts 311A, B, C may form a grid or a pattern (usually different from the pattern of the localized doped regions 306A and 306B of the back surface 303 of the substrate 301) on the front surface 302 of the substrate 301. Front electrical contacts 311A, B, C in FIG. 3G are formed by depositing an electrically conductive composition, such as a dispersion or a paste, on the front surface 302 of the substrate 301. Upon firing, the metal of the conductive compositing penetrates the passivating layer 309 on the front surface surface 302 of the substrate 301 to form an ohmic contact with the doped semiconductor layer 307A. FIG. 3G presents the front electrical contacts 311A, B, C after the firing so that the elements 311A, B, C form an ohmic contact with the doped semiconductor layer 307A.

Elements 312A and 312B represent individual features of the patterned conducting layer of the back contact, while element 313 represents the unpatterned conducting layer. FIG. 3G illustrates that the pattern of the patterned conducting layer matches the pattern of the localized doped regions on the back surface of the substrate so elements 312A and 312B of the patterned conducting layer match corresponding localized doped regions 306A and 306B. Elements 312A and 312B in FIG. 3G are formed by depositing an electrically conductive composition, such as a dispersion or a paste, on the back surface 303 of the substrate 301 to form the patterned conducting layer. The unpatterned conducting layer 313 is formed by depositing an electrically conductive composition, such as a dispersion or a paste, over the patterned conducting layer. Upon firing, elements 312A and 312B establish an ohmic contact with their corresponding localized doped regions 306A and 306B by penetrating through the passivating layer 310 on the back surface 303 of the substrate 301. Upon firing, elements 312A and 312B penetrate the passivating layer 310 to form an ohmic contact with patterned doped layers 306A and 306B, as well as establish an ohmic contact with the unpatterned conducting layer 313.

One advantage of the present method with respect to the process of US 2013-0153019 is that the use of the capping composition in the present method allows one to make the doped regions (illustrated as elements 306A and 306B in FIG. 3) on the back surface of the substrate more localized compared to similar doped regions formed according to the process of US 2013-0153019 without the use of the capping composition. For example, when the first (doping) composition comprises boron containing material, while diffusing into substrate, boron of the doping composition may spread over regions outside the areas defined by individual features (illustrated by elements 304A and 304B) of the pattern of the doping composition in the absence of the capping composition. The capping composition may reduce and/or eliminate such undesirable spreading. Also the use of the capping composition may allow eliminating penetration of a dopant from the gaseous doping ambient into the doped regions (such as regions 306A and 306B) on the back surface of the substrate during the formation of the doped semiconductor layer 307 (307A and 307B). For example, in the case of boron doped localized regions on the back surface of the substrate the capping composition may eliminate penetration of phosphorus from the gaseous doping ambient, such as POCl₃ containing ambient, into the boron doped regions. A further advantage is in the metallization scheme for the rear side. Using point contacts to contact patterned doped regions with a low cost unpatterned metal layer may significantly reduce the cost of metallization compared to the process described in US 2013-0153019.

The present invention can be illustrated in more details by the following examples, however, it should be understood that the present invention is not limited thereto.

### EXAMPLE

High efficiency solar cells were prepared as follows.
Monocrystalline p-type silicon wafers (illustrated in FIG. 3A as 301) were textured in a KOH solution to form random pyramid texture for enhanced light trapping. After texturing, the substrates were cleaned in a mixture of HF:HCl to remove residual contaminants from the surface.

Wafers 301 were then printed with a doping ink (elements 304A and 304B in FIG. 3B) containing a boron-containing material, a silicon dioxide ceramic particle, a polymer binder, and an organic solvent to enable printability of the ink (formulations disclosed in U.S. provisional application No. 61/734,014). This ink contained 20% titanium diboride, 7.8% silica particles, 7.5% polybutyl methacrylate binder, and 64.7% of terpineol-based solvent. The doping ink pattern was an array of dots, with a pitch around 1 mm and a dot diameter of approximately 300 μm. After printing, the wafers were baked in an inline belt furnace with a peak temperature of around 200° C. and a time of approximately 45 seconds.

The wafers 301 were printed with a capping ink (elements 305A and 305B in FIG. 3C) containing silicon nanoparticles and other ceramic particles (formulations disclosed in U.S. provisional application No. 61/734,014) (10 wt % silicon nanoparticles, 1.4% polybutyl methacrylate binder, 88.6% of terpineol-based solvent). The pattern of the capping ink matched the pattern of the doping ink and was aligned to the first pattern. The dot diameter of the capping ink pattern is larger than that of the first pattern, approximately 450 μm, to allow for alignment tolerances. After printing, the wafers were baked in an inline belt furnace with a peak temperature of around 200° C. and a time of approximately 45 seconds.

Next the wafers are cleaned in a solution of HF:HCl (7% HF and 5% HCl in DI water) and then loaded into a quartz diffusion furnace at a temperature of 800° C. in an N₂:O₂ ambient. After loading, the furnace temperature was increased to 925° C. for 1 hour to drive the boron from the ink into the substrate.

Next, the furnace was ramped down to approximately 850° C. and POCl₃ gas was flowed with an ambient containing N₂ and O₂ for 20 minutes. After phosphorous diffusion, the furnace was ramped down in N₂ ambient to 800° C. and unloaded. Optionally, an additional oxidation step and optionally an additional drive-in step (same or higher temperature) can also be added to create a lightly-doped emitter. The resulting wafer is schematically shown in FIG. 3D, where n-type diffused region 307 (307A+307B) is formed on the wafer outside of the ink printed regions. P-type diffused regions 306A and 306B are created as result of dopant diffusion from the doping ink 304A and 304B into the wafer 301.

After diffusion, the phosphosilicate glass (PSG) and residual ink was removed from the samples in a solution of HF:HCl. Optionally, an additional ultra-sonication step may be added to remove remaining ink particles from the rear surface. Subsequently, the rear side of the wafer was etched in a silicon etchant such that doped regions between ink-printed areas are substantially etched while the ink-printed regions are not affected by the etchant. Examples of silicon etch chemistry include potassium hydroxide (KOH) solutions, sodium hydroxide (NaOH) solutions, or acidic etch chemistries such as mixtures of nitric (HNO₃) and hydrofluoric (HF) acids. The details of this process are described, for example, in US 2013-0153019. Next, wafers were cleaned in the hot mixture of H₂O₂, HCl and water, followed by HF:HCl to prepare wafers for passivation layer deposition. The resulting wafer is schematically shown in FIG. 3E, where p-type regions 306A and 306B on the rear side of the wafer are well isolated from the n-type regions 307A on the front side of the wafer. As a result of etching and cleaning processes, substantial parts of printed inks were removed from the wafer, leaving an ink residue 308A and 308B.

In FIG. 3F, silicon nitride passivation layers 309 and 310 were then deposited on the front and on the rear side of the wafers using a plasma enhanced chemical vapor deposition (PECVD) tool. Passivation layer 309 had a refractive index (RI) of about 2.1 and a thickness of approximately 100 nm as measured on a polished Si wafer. The rear side passivation layer 310 had an RI of 2.1 and thickness of about 150 nm, as measured on a polished wafer. Alternatively, other passivation layers or passivation layer stacks could be used on the rear side; examples include SiO2, Al2O3, SiO2/SiNx, Al2O3/SiNx.

Next as illustrated in FIG. 3G, metal contacts were deposited on front and rear side of the wafers, typically by screen printing. The front contacts 311A, B and C were printed using a standard Ag paste (commercially available as DuPont™ Solamet® PV17F) designed to fire through the nitride layer and contact the heavily n+ doped silicon underneath (front phosphorous diffusion layer or emitter). The rear side of the wafer had two layers of metal printed. First layer (illustrated by elements 312A and 312B in FIG. 3G) is a Ag or Ag:Al paste printed in the pattern that matched and was aligned to the first ink layer. The metal dot size was around 100 μm. After the first layer was printed, a second layer 313 of blanket aluminum metal, thickness about 40 μm, was printed over the first one to connect all metal contacts together. The blanket metal paste contained at least one of aluminum, tin, nickel, copper. Finally, the wafer was fired in a conveyor firing furnace at a maximum temperature of about 800° C.

### Experiment 1

### Impact of Drive-in Conditions

Monocrystalline p-type silicon wafers were textured in a KOH solution to form random pyramid texture for enhanced light trapping. After texturing, the substrates were cleaned in a mixture of HF:HCl to remove residual contaminants from the surface.

Wafers were then printed with a doping ink containing a boron-containing material and a ceramic particle The pattern is either comprised of a set of fingers approximately 300 μm wide with a pitch of about 1 mm and three 1.8 mm wide busbars (for sheet resistance measurements) or comprised of an array of dots, with a pitch around 1 mm and dot diameter of approximately 300 μm (for solar cell fabrication). After printing, the wafers were baked in an inline belt furnace with a peak temperature of around 200° C. and a time of approximately 45 seconds.

Next the wafers were printed with a capping ink containing silicon nanoparticles and other ceramic particles. The pattern of the capping ink matches the pattern of the doping ink and were aligned to the first pattern. The features of the capping ink are about 200 μm wider than those of the first pattern to allow for alignment tolerances. After printing, the wafers were baked in an inline belt furnace with a peak temperature of around 200° C. and a time of approximately 45 seconds.

Next the wafers were cleaned in a solution of HF:HCl (7% HF and 5% HCl in DI water) and then loaded into a quartz diffusion furnace at a temperature of 800° C. in an N₂:O₂ ambient. After loading, the furnace temperature was increased to a drive-in temperature between 900 C and 975 C for 1 hour to drive the boron from the ink into the substrate.

Next, the furnace was ramped down to approximately 850° C. and POCl₃ gas was flowed with an ambient containing N₂ and O₂ for 20 minutes. After phosphorous diffusion, the furnace was ramped down in N₂ ambient to 800° C. and unloaded. After diffusion, the PSG and residual ink was removed from the samples in a solution of HF:HCl. Optionally, an additional ultra-sonication step may be added to remove remaining ink particles from the rear surface. (In the experiments presented in this section, this optional step was included) Subsequently, the rear side of the wafer was etched in a silicon etchant such that doped regions between ink-printed areas are substantially etched while the ink-printed regions are not affected by the etchant. Examples of silicon etch chemistry include potassium hydroxide (KOH) solutions, sodium hydroxide (NaOH) solutions, or acidic etch chemistries such as mixtures of nitric (HNO3) and hydrofluoric (HF) acids. Next, wafers were cleaning in the hot mixture of H2O2, HCl and water, followed by HF:HCl to prepare wafers for passivation layer deposition.

Silicon nitride passivation layers were then deposited on the front and on the rear side of the wafers using a PECVD tool. The front nitride used had a refractive index (RI) of about 2.1 and a thickness of approximately 100 nm as measured on a polished Si wafer. The rear side silicon nitride has an RI of 2.3 and thickness of about 40 nm, as measured on a polished wafer.

The wafers with the dot ink pattern were processed further to be made into solar cells by providing metal contacts as follows. Metal contacts were deposited on front and rear side of the wafers, typically by screen printing. The front side of the cell uses a standard Ag paste designed to fire through the nitride layer and contact the heavily n+ doped silicon underneath (front phosphorous diffusion layer or emitter). The rear side of the cell has two layers of metal printed. The first layer was a Ag or Ag:Al paste printed in the pattern that matches and was aligned to the first ink layer. The metal dot size was around 150 μm. The wafer was then fired in the firing furnace at a peak temperature of around 800 C. Further, a second blanket layer of Ag metal, thickness about 10 μm, was printed over the rear side contacts one to connect all metal contacts together. Afterwards the wafers are baked at a temperature of about 300 C.

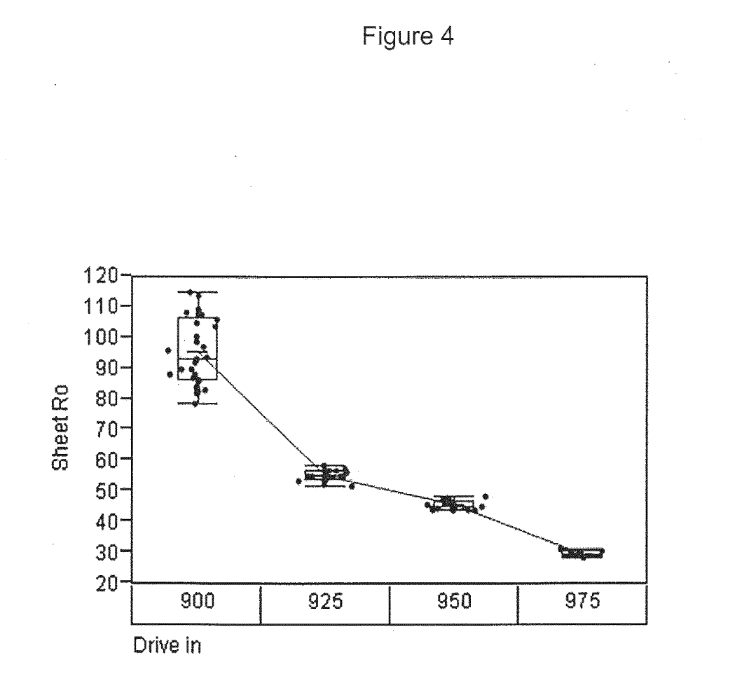

Sheet resistance measurements were then performed on the wafers with the finger/busbar pattern using a four-point-probe technique. Measurements were done across the busbars such that the measurement probes were aligned parallel to the busbar and the probe-head is stepped across the busbar in short steps. This way a sheet resistance of the doped ink regions can be extracted. FIG. 4 shows dependence of sheet resistance of the ink regions extracted from these measurements as function of the drive-in temperature. Clearly, a wide range of boron doping strengths can be achieved by changing drive-in conditions.

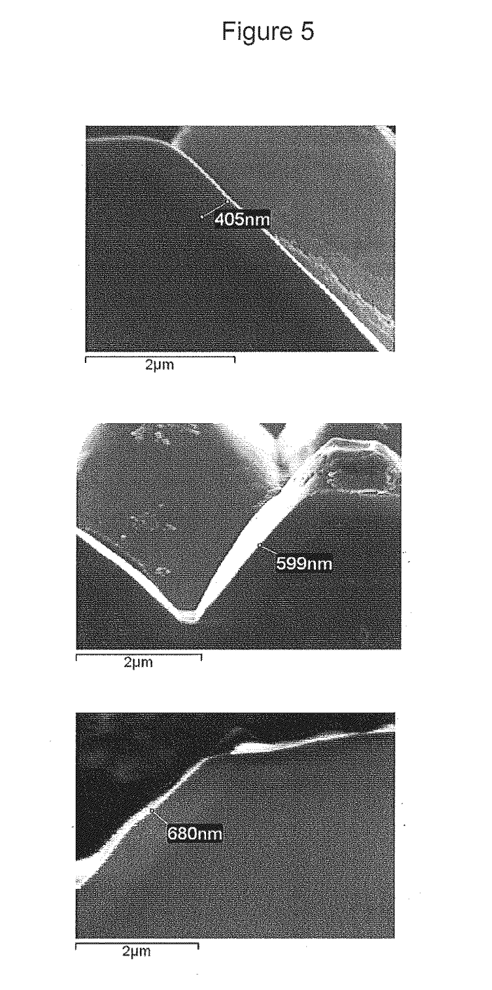

FIG. 5 shows cross-section Scanning Electron Microscopy (SEM) images of the ink printed regions of these wafers. Contrast seen on these images originates from the heavy p-type doping at the wafer surface. Clearly, higher thermal budget of the drive-in process yields deeper diffusion consistent with the lower sheet resistance. Table 1 shows solar cell efficiency results, obtained under simulated AM1.5G spectrum.

TABLE 1

| Drive-in | | Jsc | | |
|---|---|---|---|---|
| Temperature | Voc (V) | (mA/cm2) | FF(%) | Efficiency (%) |
| 900 | 628 | 37.8 | 75.2 | 17.9 |
| 925 | 634 | 38.4 | 76 | 18.5 |
| 950 | 632 | 38 | 76.2 | 18.3 |
| 975 | 633 | 37.9 | 76.5 | 18.4 |

### Experiment 2

### Impact of Selective Etch Time

Monocrystalline p-type silicon wafers were textured in a KOH solution to form random pyramid texture for enhanced light trapping. After texturing, the substrates were cleaned in a mixture of HF:HCl to remove residual contaminants from the surface.

Wafers were then printed with a doping ink containing a boron-containing material and a ceramic particle. The pattern of the doping ink formed a set of fingers approximately 300 μm wide with a pitch of about 1 mm and three 1.8 mm wide busbars. After printing, the wafers were baked in an inline belt furnace with a peak temperature of around 200° C. and a time of approximately 45 seconds.

Next the wafers were printed with a capping ink containing silicon nanoparticles and other ceramic particles. The pattern of the capping ink matches the pattern of the doping ink and is aligned to the first pattern. The features of the capping ink are about 200 μm wider than those of the first pattern to allow for alignment tolerances. After printing, the wafers were baked in an inline belt furnace with a peak temperature of around 200° C. and a time of approximately 45 seconds.

Next the wafers were cleaned in a solution of HF:HCl (7% HF and 5% HCl in DI water) and then loaded into a quartz diffusion furnace at a temperature of 800° C. in an N₂:O₂ ambient. After loading, the furnace temperature was increased to 925° C. for 1 hour to drive the boron from the ink into the substrate.

Next, the furnace was ramped down to approximately 850° C. and POCl₃ gas was flowed with an ambient containing N₂ and O₂ for 20 minutes. After phosphorous diffusion, the furnace was ramped down in N₂ ambient to 800° C. and unloaded. Optionally, an additional oxidation step and optionally an additional drive-in step (same or higher temperature) could also be added to create a lightly-doped emitter. (In the experiments of this section, this optional step was omitted)

After diffusion, the PSG and residual ink was removed from the samples in a solution of HF:HCl. Optionally, an additional ultra-sonication step may be added to remove remaining ink particles from the rear surface. Subsequently, rear side of the wafer was etched in a silicon etchant such that doped regions between ink-printed areas are substantially etched while the ink-printed regions are not affected by the etchant. The etching process in this experiment was done using a mixture of 25% KOH, 6% IPA and 69% H2O kept at 50 C. Process time was varied in the range of 0.5 and 4 min. Next, wafers were cleaned in the hot mixture of H2O2, HCl and water, followed by HF:HCl to prepare wafers for passivation layer deposition.

Silicon nitride passivation layers were then deposited on the front and on the rear side of the wafers using a PECVD tool. The front nitride used had a refractive index (RI) of about 2.1 and a thickness of approximately 100 nm as measured on a polished Si wafer. The rear side silicon nitride had an RI of 2.3 and thickness of about 40 nm, as measured on a polished wafer.

Next, metal contacts were deposited on front and rear side of the wafers, typically by screen printing. The front side of the cell used a standard Ag paste (commercially available as DuPont™ Solamet® PV17F) designed to fire through the nitride layer and contact the heavily n+ doped silicon underneath (front phosphorous diffusion layer or emitter). Ag:Al metal paste was printed on the rear side in the pattern matching the pattern of the ink. The metal paste pattern was aligned to the ink pattern. Finger width of the metal pattern was about 100 μm. Finally, solar cells were fired in the firing furnace at a peak temperature of about 800 C.

Table 2 shows solar cell efficiency results, obtained under simulated AM1.5G spectrum.

TABLE 2
Impact of selective etch time on localized BSF cell efficiency.
H-bar rear side pattern was used in this experiment.

| Etch | Si | | | | Shunt | |
|---|---|---|---|---|---|---|
| time | removed | | Jsc | | Resistance | Efficiency |
| (min) | (um) | Voc (V) | (mA/cm2) | FF(%) | (Ohm) | (%) |
| 0.5 | 0.3 | 611 | 36.6 | 75 | 1.3 | 16.8 |
| 1 | 0.4 | 617 | 37.1 | 76.6 | 3.1 | 17.5 |
| 2 | 0.5 | 621 | 37.6 | 78.1 | 30 | 18.2 |
| 4 | 1.1 | 619 | 37.6 | 78.0 | 28 | 18.2 |

### Experiment 3

### Impact of Silicon Nitride Conditions

Monocrystalline p-type silicon wafers were textured in a KOH solution to form random pyramid texture for enhanced light trapping. After texturing, the substrates were cleaned in a mixture of HF:HCl to remove residual contaminants from the surface.

Wafers were then printed with a doping ink containing a boron-containing material and a ceramic particle. The doping ink pattern was an array of dots, with a pitch around 1 mm and dot diameter of approximately 300 μm. After printing, the wafers were baked in an inline belt furnace with a peak temperature of around 200° C. and a time of approximately 45 seconds.

Next the wafers were printed with a capping ink containing silicon nanoparticles and other ceramic particles. The pattern of the capping ink matches the pattern of the doping ink and is aligned to the first pattern. The dot diameter of the capping ink pattern was larger than that of the first pattern, approximately 450 μm, to allow for alignment tolerances. After printing, the wafers were baked in an inline belt furnace with a peak temperature of around 200° C. and a time of approximately 45 seconds. Next the wafers were cleaned in a solution of HF:HCl (7% HF and 5% HCl in DI water) and then loaded into a quartz diffusion furnace at a temperature of 800° C. in an N₂:O₂ ambient. After loading, the furnace temperature was increased to 925° C. for 1 hour to drive the boron from the ink into the substrate.

Next, the furnace was ramped down to approximately 850° C. and POCl₃ gas was flowed with an ambient containing N₂ and O₂ for 20 minutes. After phosphorous diffusion, the furnace was ramped down in N₂ ambient to 800° C. and unloaded. After diffusion, the PSG and residual ink was removed from the samples in a solution of HF:HCl. Optionally, an additional ultra-sonication step may be added to remove remaining ink particles from the rear surface. (In the experiments of the present section, this optional step was performed). Subsequently, the rear side of the wafer was etched in a silicon etchant such that doped regions between ink-printed areas were substantially etched while the ink-printed regions are not affected by the etchant. Examples of silicon etch chemistry include potassium hydroxide (KOH) solutions, sodium hydroxide (NaOH) solutions, or acidic etch chemistries such as mixtures of nitric (HNO₃) and hydrofluoric (HF) acids. Next, wafers were cleaned in the hot mixture of H₂O₂, HCl and water, followed by HF:HCl to prepare wafers for passivation layer deposition.

Silicon nitride passivation layers were then deposited on the front and on the rear side of the wafers using a PECVD tool. The front nitride used had a refractive index (RI) of about 2.1 and a thickness of approximately 100 nm as measured on a polished Si wafer. The rear side silicon nitride had an RI of 2.1 and a range of different thicknesses, between about 100 nm and 200 nm, as measured on a polished wafer.

Next, metal contacts were deposited on the front and rear side of the wafers, typically by screen printing. The front side of the cell used a standard Ag paste (commercially available as DuPont™ Solamet® PV17F) designed to fire through the nitride layer and contact the heavily n+ doped silicon underneath (front phosphorous diffusion layer or emitter). The rear side of the cell had two layers of metal printed. The first layer was a Ag or Ag:Al paste printed in the pattern that matches and was aligned to the first ink layer. The metal dot size was around 100 μm. After the first layer was printed, a second layer of blanket aluminum metal paste, thickness about 40 μm, was printed over the first one to connect all metal contacts together. The wafers were then fired in a conveyor firing furnace at a maximum temperature of about 800° C.

Tables 3A and 3B show impact of rear side silicon nitride thickness on solar cell efficiency. Table 3A show results when a relatively aggressive Al paste (paste A) is used on the rear side; it is clear that a thicker silicon nitride thickness, about 150 nm, is required to achieve optimum solar cell efficiency. Table 3B shows results of experiment using another Al paste, paste B; clearly a broader range of silicon nitride thicknesses can be used in this case.

TABLE 3A
Impact of rear side silicon nitride thickness
on solar cell efficiency (Al paste A)

| Thickness | | Jsc | | |
|---|---|---|---|---|
| (nm) | Voc (V) | (mA/cm2) | FF(%) | Efficiency (%) |
| 100 | 624 | 36.8 | 76.5 | 17.6 |
| 120 | 626 | 37.2 | 77 | 17.9 |
| 150 | 630 | 37.4 | 77 | 18.1 |
| 175 | 631 | 37.6 | 75.5 | 17.9 |
| 200 | 632 | 37.6 | 72 | 17.1 |

TABLE 3B
Impact of rear side silicon nitride thickness
on solar cell efficiency (Al paste B)

| Thickness | | Jsc | | |
|---|---|---|---|---|
| (nm) | Voc (V) | (mA/cm2) | FF(%) | Efficiency (%) |
| 100 | 634 | 38.1 | 77.3 | 18.6 |
| 150 | 633 | 38.1 | 77.0 | 18.6 |

Although the foregoing refers to particular preferred embodiments, it will be understood that the present invention is not so limited. It will occur to those of ordinary skill in the art that various modifications may be made to the disclosed embodiments and that such modifications are intended to be within the scope of the present invention.

All of the publications, patent applications and patents cited in this specification are incorporated herein by reference in their entirety.

What is claimed is:

1. A method of making a solar cell comprising:
(a) obtaining a semiconductor substrate that is doped with a second dopant, the substrate having a front surface and a back surface;
(b) depositing a first ink on the back surface of the substrate in a first pattern, the first ink comprising a first dopant, the first dopant being of the same type as the second dopant;
(c) then, depositing a second ink over the deposited first ink on the back surface of the substrate in a second pattern, the second pattern matching the first pattern and the second ink comprising a set of undoped semiconductor nanoparticles;
(d) then, heating the semiconductor substrate so that the first dopant diffuses into the substrate and thereby, forms a third pattern of localized doped regions;
(e) then, exposing the substrate to a doping ambient comprising a third dopant, thereby forming a doped semiconductor layer on the front surface and a portion of the back surface not covered by the second ink, the third dopant is of the opposite type to the second dopant;
and
(f) then, removing the deposited first and second inks.

2. The method of claim 1, wherein the semiconductor substrate is a silicon substrate, the second dopant is a p-dopant.

3. The method of claim 2, wherein the first dopant comprises boron.

4. The method of claim 3, wherein said heating occurs at a temperature ranging from 900 to 975° C.

5. The method of claim 2, wherein the doping ambient is a phosphorous deposition ambient.

6. The method of claim 5, wherein the doping ambient comprises POCl₃.

7. The method of claim 2, wherein the set of undoped semiconductor nanoparticles is a set of silicon nanoparticles.

8. The method of claim 1, wherein said exposing step (e) comprises forming a doped semiconductor oxide layer on the front surface and the portion of the back surface not covered by the second ink and wherein said removing step (f) comprises removing said doped semiconductor oxide layer.

9. The method of claim 1, wherein said removing step (f) results in preserving at least a portion of the deposited first ink and wherein the method further comprises exposing the back surface to a semiconductor etchant so that a portion of the localized doped regions not covered by the deposited first ink is etched out by the etchant, while a portion of the localized doped regions covered by the deposited first ink remains intact.

10. The method of claim 1, further comprising depositing a passivating layer on the front surface and the back surface.

11. The method of claim 10, wherein the passivating layer comprises at least one of silicon nitride, aluminum oxide and silicon oxide.

12. The method of claim 11, wherein the passivating layer on the back surface is a stack structure comprising i) silicon nitride and ii) at least one of silicon oxide and aluminum oxide.

13. The method of claim 1, further comprising depositing an electrical contact on the back surface.

14. The method of claim 13, wherein said depositing the electrical contact comprises (i) depositing a patterned metal layer on the back surface in a fourth pattern, said fourth pattern matching the first pattern and (ii) depositing an unpatterned metal layer over the patterned metal layer.

15. The method of claim 14, wherein depositing the patterned metal layer comprises depositing a metal paste.

16. The method of claim 15, wherein said metal paste comprises at least one of Ag and Al.

17. The method of claim 14, wherein the unpatterned metal layer comprises at least one of Ag and Al.

18. The method of claim 13, further comprising depositing a metal contact grid on the front surface.

19. The method of claim 13, further comprising exposing the substrate to an elevated temperature ranging from 700° C. to 900° C.

20. A method of making a solar cell comprising:
(a) obtaining a p-doped silicon substrate, the substrate having a front surface and a back surface;
(b) depositing a first ink on the back surface of the substrate in a first pattern, the first ink comprising a boron containing compound and a first solvent;
(c) then, depositing a second ink over the deposited first ink on the back surface of the substrate in a second pattern, the second pattern matching the first pattern and the second ink comprising a set of undoped silicon nanoparticles and a second solvent;
(d) then, heating the substrate so that the boron of the deposited first ink diffuses into the substrate and thereby, forms a pattern of localized doped regions;
(e) then, exposing the substrate to a phosphorous deposition ambient, thereby forming a phosphosilicate glass layer and a phosphorous diffusion layer on the front surface and a portion of the back surface not covered by the second ink;
(f) then, removing the deposited second ink and the phosphosilicate glass layer;
(g) exposing the back surface to a selective silicon etchant so that a portion of the localized doped regions not covered by the deposited first ink is etched out by the etchant, while a portion of the localized doped regions covered by the deposited first ink remains intact;
(h) depositing a passivating layer on the front surface and the back surface;
(i) depositing an first electrical contact on the front surface and depositing a second electrical contact on the back surface, wherein said depositing the second electrical contact comprises depositing a patterned metal layer on the back surface in a fourth pattern, said fourth pattern matching the first pattern and depositing a unpatterned metal layer over the patterned metal layer; and
(j) then exposing the substrate to an elevated temperature ranging from 700° C. to 900° C.

21. A solar cell made by the method of claim 1.
